(19) United States
(12) Patent Application Publication
(10) Pub. No.: US 2026/0367120 A1
(43) Pub. Date: Nov. 19, 2026

(54) Maximum Power Estimation for Wireless Power Transfer

(71) Applicant: Apple Inc., Cupertino, CA (US)

(72) Inventors: Weihong Qiu, San Ramon, CA (US); Jukka-pekka J Sjoeroos, Cupertino, CA (US); Guangqi Zhu, Santa Clara, CA (US)

(21) Appl. No.: 19/641,006

(22) Filed: Apr. 7, 2026

Related U.S. Application Data
(60) Provisional application No. 63/806,759, filed on May 16, 2025.

(51) Int. Cl. G01R 21/06; H02J 50/12

(52) U.S. Cl. CPC G01R 21/06; H02J 50/12

(57) ABSTRACT

Determining a maximum power transfer level associated with a wireless power transfer (WPT) link between a wireless power transmitter (PTx) and a wireless power receiver (PRx) can include operating an inverter of the PTx to establish a lower power WPT link with the PRx; using control circuitry of the PTx to determine a maximum power level associated with the WPT link by operating the PTx at a plurality of operating points; measuring one or more circuit parameters associated with the plurality of operating points; computing one or more characterizing parameters from the measured one or more circuit parameters; and computing the maximum power level from the one or more characterizing parameters. The maximum power level can be used to operate the inverter to transition to a higher power level WPT link, wherein the higher power level is based on the determined maximum power level associated with the WPT link.

### BACKGROUND

Wireless power transfer is used in various electronic devices. For example, smart phones, tablet computers, smart watches, wireless earphones, styluses, etc. may employ wireless power transfer to facilitate charging of batteries within the devices and/or to power the devices during operation.

### SUMMARY

A wireless power transmitter including a wireless power transfer coil, an inverter that drives the wireless power transfer coil to deliver power to a wireless power receiver coupled to the wireless power transfer coil, and control circuitry coupled to the wireless power transfer coil and the inverter can operate the inverter to establish a first power wireless power transfer link with the wireless power receiver; determine a maximum power level associated with the wireless power transfer link; and transition to a second power level wireless power transfer link, wherein the second power level is higher than the first power level and is based on the determined maximum power level associated with the wireless power transfer link. The control circuitry can determine the maximum power level associated with the wireless power transfer link by operating the wireless power transmitter at a plurality of operating points; measuring one or more circuit parameters associated with the plurality of operating points; computing one or more characterizing parameters from the measured one or more circuit parameters; and computing the maximum power level from the one or more characterizing parameters.

The plurality of operating points can include three operating points, each operating point corresponding to an input voltage Vin, and output current Io, and a load resistance Ro. The one or more characterizing parameters can include a gain g, a wireless power transfer system resistance Rs, and a wireless power transfer system reactance Xs. The one or more characterizing parameters and the operating points can be related by:

$${g}^{2} V {in}^{2} = {I}_{o}^{2} {Xs}^{2} + {{I}_{o}^{2} ( Rs + {R}_{o} )}^{2} .$$

The maximum power level can be computed by:

$${P}_{max} = \frac{{g}^{2} V {in}_{max}^{2}}{{Xs}^{2} + {( Rs + Ro )}^{2}} Ro .$$

The plurality of operating points can include two operating points, each operating point corresponding to an output voltage Vo and an output current Io. The one or more characterizing parameters can include a gain g and a wireless power transfer system impedance Zo, wherein the wireless power transfer system Zo is a resistance. The one or more characterizing parameters and the operating points can be related by:

gVin=IoZo+Vo.

The maximum power level can be computed for a fixed load resistance RL by:

$${P}_{max} = \frac{{( {g V in}_{max} )}^{2}}{{( Zo + RL )}^{2}} RL .$$

The maximum power level can be computed for a fixed output voltage Vo_{target} by:

$${P}_{max} = \frac{{g V in}_{max} - {V o}_{target}}{Zo} {V o}_{target} .$$

the maximum power level can be computed for a fixed output current Io_{target} by:

Pₘₐₓ=(gVinₘₐₓ−Zo·Io_{target})Io_{target}.

A method of determining a maximum power transfer level associated with a wireless power transfer link between a wireless power transmitter and a wireless power receiver can include operating an inverter of the wireless power transmitter to establish a lower power wireless power transfer link with the wireless power receiver; using control circuitry of the wireless power transmitter to determine a maximum power level associated with the wireless power transfer link by operating the wireless power transmitter at a plurality of operating points; measuring one or more circuit parameters associated with the plurality of operating points; computing one or more characterizing parameters from the measured one or more circuit parameters; and computing the maximum power level from the one or more characterizing parameters. The method can further include operating the inverter to transition to a higher power level wireless power transfer link, wherein the higher power level is based on the determined maximum power level associated with the wireless power transfer link.

The plurality of operating points can include three operating points, each operating point corresponding to an input voltage Vin, and output current Io, and a load resistance Ro. The one or more characterizing parameters can include a gain g, a wireless power transfer system resistance Rs, and a wireless power transfer system reactance Xs. The one or more characterizing parameters and the operating points can be related by:

$${g}^{2} V {in}^{2} = {I}_{o}^{2} {Xs}^{2} + {{I}_{o}^{2} ( Rs + {R}_{o} )}^{2} .$$

The maximum power level can be computed by:

$${P}_{max} = \frac{{g}^{2} V {in}_{max}^{2}}{{Xs}^{2} + {( Rs + Ro )}^{2}} Ro .$$

The plurality of operating points can include two operating points, each operating point corresponding to an output voltage Vo and an output current Io. The one or more characterizing parameters can include a gain g and a wireless power transfer system impedance Zo, wherein the wireless power transfer system Zo is a resistance. The one or more characterizing parameters and the operating points can be related by:

gVin=IoZo+Vo.

The maximum power level can be computed for a fixed load resistance RL by:

$${P}_{max} = \frac{{( {g V in}_{max} )}^{2}}{{( Zo + RL )}^{2}} RL .$$

The maximum power level can be computed for a fixed output voltage Vo_{target} by:

$${P}_{max} = \frac{{g V in}_{max} - {V o}_{target}}{Zo} {V o}_{target} .$$

The maximum power level can be computed for a fixed output current Io_{target} by:

Pₘₐₓ(gVinₘₐₓ−Zo·Io_{target})Io_{target}.

A wireless power transmitter can include a wireless power transfer coil, an inverter that drives the wireless power transfer coil to deliver power to a wireless power receiver coupled to the wireless power transfer coil, and control circuitry coupled to the wireless power transfer coil and the inverter. The control circuitry can operate the inverter to establish a lower power wireless power transfer link with the wireless power receiver; determine a maximum power level associated with the wireless power transfer link; and transition to a higher power level wireless power transfer link. The higher power level can be based on the determined maximum power level associated with the wireless power transfer link. The control circuitry can determine the maximum power level associated with the wireless power transfer link by computing an intersection of a profile load line of a wireless power transmitter with a power load line of a wireless power transfer system including the wireless power transmitter and the wireless power receiver. The profile load line of a wireless power transmitter can be given by:

Vo=mPo+d

and the power load line can be given by:

$$Po = \frac{{g V in}_{max} - V o}{Zo} V o$$

where Vo is an output voltage, Po is an output power, m is a slope of a linearly increasing power as a function of voltage, d is an offset value, Vinₘₐₓ is a maximum DC input voltage to the inverter, Zo is an impedance of the wireless power transfer system. The maximum power can be given by:

$${Po}_{target} = \frac{{Vo}_{target} - d}{m} .$$

### BRIEF DESCRIPTION OF THE DRAWINGS

FIG. 1 illustrates a simplified block diagram of a wireless power transfer system.

FIGS. 2A-2B illustrate positioning of a wireless power receiver and a wireless power transmitter.

FIG. 3 illustrates a simplified flowchart of a wireless power transfer initiation sequence that can be performed by a wireless power transfer system including a wireless power transmitter and a wireless power receiver.

FIG. 4 illustrates a 3-point power estimation technique.

FIG. 5 illustrates a 2-point power estimation technique.

FIG. 6 illustrates a load-line power estimation technique.

FIG. 7 illustrates exemplary accuracies of 2-point vs. 3-point power estimation techniques.

FIG. 8 illustrates exemplary accuracies of a constant load (resistance) vs. constant voltage 2-point power estimation technique.

### DETAILED DESCRIPTION

In the following description, for purposes of explanation, numerous specific details are set forth to provide a thorough understanding of the disclosed concepts. As part of this description, some of this disclosure's drawings represent structures and devices in block diagram form for sake of simplicity. In the interest of clarity, not all features of an actual implementation are described in this disclosure. Moreover, the language used in this disclosure has been selected for readability and instructional purposes, has not been selected to delineate or circumscribe the disclosed subject matter. Rather the appended claims are intended for such purpose. Any trademarks referenced herein are intended to only to identify examples and are property of their respective owners.

Various embodiments of the disclosed concepts are illustrated by way of example and not by way of limitation in the accompanying drawings in which like references indicate similar elements. For simplicity and clarity of illustration, where appropriate, reference numerals have been repeated among the different figures to indicate corresponding or analogous elements. In addition, numerous specific details are set forth to provide a thorough understanding of the implementations described herein. In other instances, methods, procedures, and components have not been described in detail so as not to obscure the related relevant function being described. References to “an,” “one,” or “another” embodiment in this disclosure are not necessarily to the same or different embodiment, and they mean at least one. A given figure may be used to illustrate the features of more than one embodiment, or more than one species of the disclosure, and not all elements in the figure may be required for a given embodiment or species. A reference number, when provided in a given drawing, refers to the same element throughout the several drawings, though it may not be repeated in every drawing. The drawings are not to scale unless otherwise indicated, and the proportions of certain parts may be exaggerated to better illustrate details and features of the present disclosure.

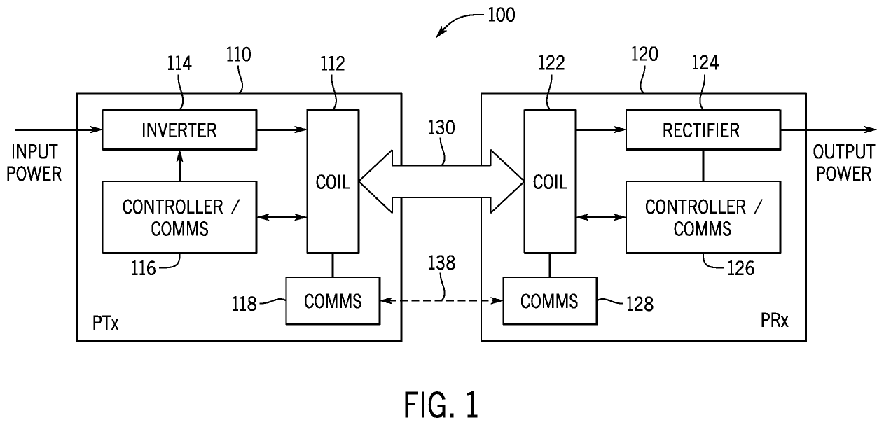

FIG. 1 illustrates a simplified block diagram of a wireless power transfer system 100. Wireless power transfer system includes a power transmitter (PTx) 110 that transfers power to a power receiver (PRx) 120 wirelessly, such as via inductive coupling 130. Power transmitter 110 may receive input power that is converted to an AC voltage having particular voltage and frequency characteristics by an inverter 114. Inverter 114 may be controlled by a controller/communications module 116 that operates as further described below. In various embodiments, the inverter controller and communications module may be implemented in a common system, such as a system based on a microprocessor, microcontroller, or the like. In other embodiments, the inverter controller may be implemented by a separate controller module and communications module that have a means of communication between them. Inverter 114 may be constructed using any suitable circuit topology (e.g., full bridge, half bridge, etc.) and may be implemented using any suitable semiconductor switching device technology (e.g., MOSFETs, IGBTs, etc. made using silicon, silicon carbide, or gallium nitride devices).

Inverter 114 may deliver the generated AC voltage to a transmitter coil 112. In addition to a wireless coil allowing magnetic coupling to the receiver, the transmitter coil block 112 illustrated in FIG. 1 may include tuning circuitry, such as additional inductors and capacitors, that facilitate operation of the transmitter in different conditions, such as different degrees of magnetic coupling to the receiver, different operating frequencies, etc. The wireless coil itself may be constructed in a variety of different ways. In some embodiments, the wireless coil may be formed as a winding of wire around a suitable bo9in. In other embodiments, the wireless coil may be formed as traces on a printed circuit board. Other arrangements are also possible and may be used in conjunction with the various embodiments described herein. The wireless transmitter coil may also include a core of magnetically permeable material (e.g., ferrite) configured to affect the flux pattern of the coil in a way suitable to the particular application. The teachings herein may be applied in conjunction with any of a wide variety of transmitter coil arrangements appropriate to a given application.

PTx controller/communications module 116 may monitor the transmitter coil and use information derived therefrom to control the inverter 114 as appropriate for a given situation. For example, controller/communications module may be configured to cause inverter 114 to operate at a given frequency or output voltage depending on the particular application. In some embodiments, the controller/communications module may be configured to receive information from the PRx device and control inverter 114 accordingly. This information may be received via the power transmission coils (i.e., in-band communication) or may be received via a separate communications channel (not shown, i.e., out-of-band communication). For in-band communication, controller/communications module 116 may detect and decode signals imposed on the magnetic link (such as voltage, frequency, or load variations) by the PRx to receive information and may instruct the inverter to modulate the delivered power by manipulating various parameters of the generated voltage (such as voltage, frequency, etc.) to send information to the PRx. In some embodiments, controller/communications module may be configured to employ frequency shift keying (FSK) communications, in which the frequency of the inverter signal is modulated, to communicate data to the PRx. Controller/communications module 116 may be configured to detect amplitude shift keying (ASK) communications or load modulation-based communications from the PRx. In either case, the controller/communications module 126 may be configured to vary the current drawn on the receiver side to manipulate the waveform seen on the Tx coil to deliver information from the PRx to the PTx. For out-of-band communication, additional modules that allow for communication between the PTx and PRx may be provided, for example, WiFi, Bluetooth, or other radio links or any other suitable communications channel.

As mentioned above, controller/communications module 116 may be a single module, for example, provided on a single integrated circuit, or may be constructed from multiple modules/devices provided on different integrated circuits or a combination of integrated and discrete circuits having both analog and digital components. The teachings herein are not limited to any particular arrangement of the controller/communications circuitry.

PTx device 110 may optionally include other systems and components, such as a separate communications module 118. In some embodiments, comms module 118 may communicate with a corresponding module tag in the PRx via the power transfer coils. In other embodiments, comms module 118 may communicate with a corresponding module using a separate physical channel 138.

As noted above, wireless power transfer system also includes a wireless power receiver (PRx) 120. Wireless power receiver can include a receiver coil 122 that may be magnetically coupled 130 to the transmitter coil 112. As with transmitter coil 112 discussed above, receiver coil block 122 illustrated in FIG. 1 may include tuning circuitry, such as additional inductors and capacitors, that facilitate operation of the transmitter in different conditions, such as different degrees of magnetic coupling to the receiver, different operating frequencies, etc. The wireless coil itself may be constructed in a variety of different ways. In some embodiments, the wireless coil may be formed as a winding of wire around a suitable bo9in. In other embodiments, the wireless coil may be formed as traces on a printed circuit board. Other arrangements are also possible and may be used in conjunction with the various embodiments described herein. The wireless receiver coil may also include a core of magnetically permeable material (e.g., ferrite) configured to affect the flux pattern of the coil in a way suitable to the particular application. The teachings herein may be applied in conjunction with any of a wide variety of receiver coil arrangements appropriate to a given application.

Receiver coil 122 outputs an AC voltage induced therein by magnetic induction via transmitter coil 112. This output AC voltage may be provided to a rectifier 124 that provides a DC output power to one or more loads associated with the PRx device. Rectifier 124 may be controlled by a controller/communications module 126 that operates as further described below. In various embodiments, the rectifier controller and communications module may be implemented in a common system, such as a system based on a microprocessor, microcontroller, or the like. In other embodiments, the rectifier controller may be implemented by a separate controller module and communications module that have a means of communication between them. Rectifier 124 may be constructed using any suitable circuit topology (e.g., full bridge, half bridge, etc.) and may be implemented using any suitable semiconductor switching device technology (e.g., MOSFETs, IGBTs, etc. made using silicon, silicon carbide, or gallium nitride devices).

PRx controller/communications module 126 may monitor the receiver coil and use information derived therefrom to control the rectifier 124 as appropriate for a given situation. For example, controller/communications module may be configured to cause rectifier 124 to operate provide a given output voltage depending on the particular application. In some embodiments, the controller/communications module may be configured to send information to the PTx device to effectively control the power delivered to the receiver. This information may be received sent via the power transmission coils (i.e., in-band communication) or may be sent via a separate communications channel (not shown, i.e., out-of-band communication). For in-band communication, controller/communications module 126 may, for example, modulate load current or other electrical parameters of the received power to send information to the PTx. In some embodiments, controller/communications module 126 may be configured to detect and decode signals imposed on the magnetic link (such as voltage, frequency, or load variations) by the PTx to receive information from the PTx. In some embodiments, controller/communications module 126 may be configured to receive frequency shift keying (FSK) communications, in which the frequency of the inverter signal has been modulated to communicate data to the PRx. Controller/communications module 126 may be configured to generate amplitude shift keying (ASK) communications or load modulation-based communications from the PRx. In either case, the controller/communications module 126 may be configured to vary the current drawn on the receiver side to manipulate the waveform seen on the Tx coil to deliver information from the PRx to the PTx. For out-of-band communication, additional modules that allow for communication between the PTx and PRx may be provided, for example, WiFi, Bluetooth, or other radio links or any other suitable communications channel.

As mentioned above, controller/communications module 126 may be a single module, for example, provided on a single integrated circuit, or may be constructed from multiple modules/devices provided on different integrated circuits or a combination of integrated and discrete circuits having both analog and digital components. The teachings herein are not limited to any particular arrangement of the controller/communications circuitry. PRx device 120 may optionally include other systems and components, such as a communications (“comms”) module 128. In some embodiments, comms module 128 may communicate with a corresponding module in the PTx via the power transfer coils. In other embodiments, comms module 128 may communicate with a corresponding module or tag using a separate physical channel 138.

Numerous variations and enhancements of the above-described wireless power transmission system 100 are possible, and the following teachings are applicable to any of such variations and enhancements.

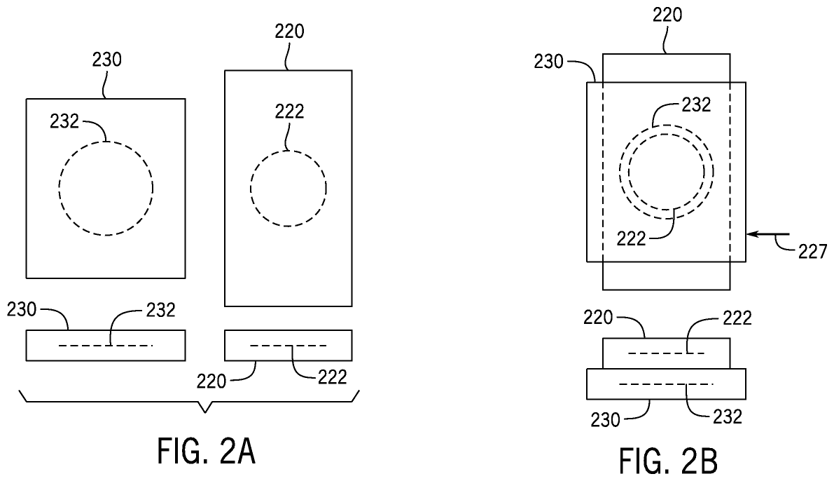

FIGS. 2A-2B illustrate an electronic device 220 (also described herein as device 220) capable of receiving (and optimally transmitting) power wirelessly and a wireless power transmitter (PTx) 230 capable of transmitting (and optionally also receiving) power wirelessly. In some embodiments, device 220 can be a smartphone, although it could be other types of electronic device, such as a tablet computer, a notebook computer, etc. PRx 230 be wireless charging puck or stand, or could alternatively be a smartphone or other type of electronic device, such as a tablet computer, a notebook computer, etc.

FIG. 2A illustrates electronic device 220 and PTx 230 separated from one another in both a plan and sectional view. FIG. 2B illustrates electronic device 220 and PTx 230 overlapping as they would be positioned to facilitate wireless power transfer from PTx 230 to device 220. As illustrated, this overlapping allows for alignment of the respective wireless power transfer coils to facilitate wireless power transfer. Finally, also depicted in FIG. 2B, an external power source 227 may also be connected to electronic PTx 230. When such an external power source is connected, power from the external power source 227 can be delivered to electronic device 220 by wireless power transmission from PTx 230.

In a wireless power transfer system, such as one including a wireless power transmitter (PTx) 110/230 and a wireless power receiver (PRx) 120/220, it may be advantageous to estimate the maximum power deliverable over the wireless power transfer link 130 between the respective devices. In some cases this can allow for the devices to establish a higher level of power transfer, which can accelerate activities such as battery charging. Additionally, the control circuitry of the wireless power transmitter (e.g., controller and communication circuitry 116) and/or the control circuitry of the wireless power receiver (e.g., controller and communication circuitry 126) may be able to provide enhanced operational stability in certain condition by knowing the maximum power that the wireless power transfer link can support. This maximum power can be affected by the electrical and magnetic properties of the wireless power transmitter, electrical and magnetic properties of the wireless power receiver, and the relative positioning of the two devices with respect to one another.

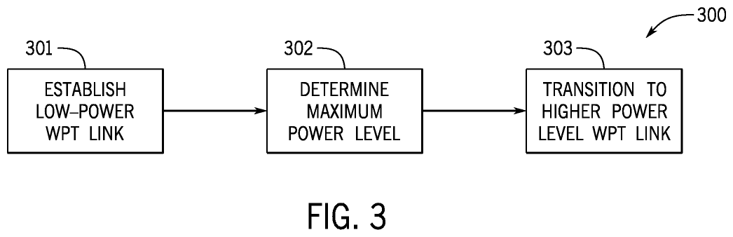

FIG. 3 illustrates a simplified flowchart 300 of a wireless power transfer initiation sequence that can be performed by a wireless power transfer system including a wireless power transmitter and a wireless power receiver, as described above. Beginning with block 301, the devices can establish a low-power wireless power transfer link. By “low-power,” it is meant that the level of power transferred is less than a maximum power level that one or both devices are capable of. For example, such a low-power mode might be limited to a maximum power level of 5 W, 7.5 W, 15 W, etc. This low-power mode can be specified by one or more industry standard protocol, such as the Qi wireless power transfer standards and protocols promulgated by the Wireless Power Consortium. This establishment of a low-power wireless power transfer link between the respective devices can include multiple device or object detection operations, communication messages, and the like performed by one or both of the wireless power receiver and the wireless power transmitter. The end result can be the establishment of a wireless power transfer link that allows wireless power to be delivered from the wireless power transmitter to the wireless power receiver at such an initial low-power level.

Thereafter, in block 302, one or both devices can separately or cooperatively estimate the maximum power level that the wireless power transfer link can support. As noted above, can be a property of the electrical and magnetic properties of the respective devices, as well as their relative positioning. The maximum power determination can be performed by the control and communication circuitry of one or the other device performing various measurements and calculations based on various operating conditions of the wireless power transfer system in the low power mode. Exemplary methods for so doing are described in greater detail below, and these, too, may be part of an industry standard, such as the Qi standards referenced above.

Once the maximum power level that the wireless power transfer link can support has been determined, in block 303, the devices can negotiate and execute a transition to a higher power level wireless power transfer link. This negotiation and execution can also be performed according to one or more industry standards, such as the Qi standards referenced above. This higher power level can support higher levels of wireless power transfer between the wireless power transmitter and the wireless power receiver, such as a power level of 15 W, 20 W, 25 W, 28 W, 30 W, 40 W, 50 W, 60 W, etc. In general, the higher power level may be selected to be less than or equal to the maximum power level that the wireless power transfer link can supported as determined in block 302.

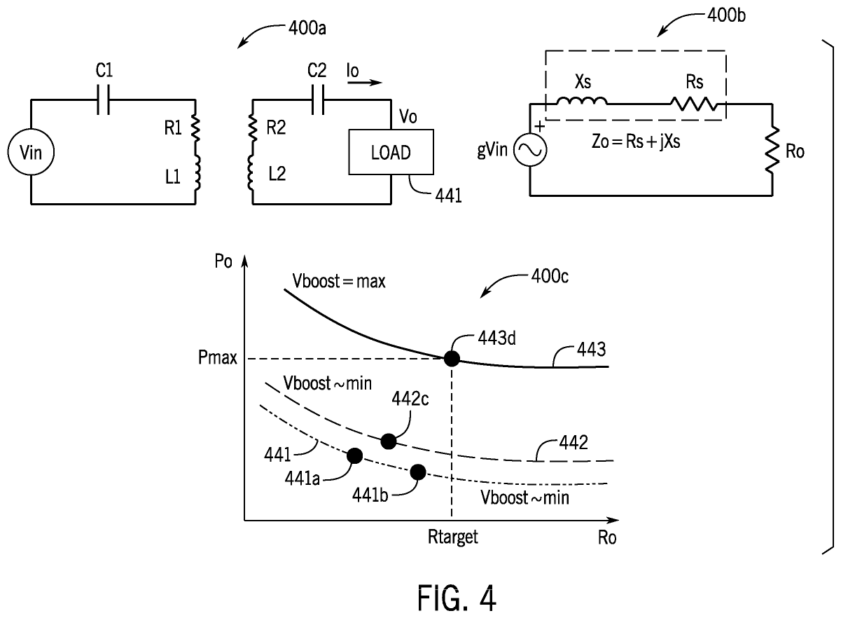

In some embodiments, the maximum power level that a wireless power transfer link can support can be determined in accordance with a three-point power estimation scheme as depicted in FIG. 4. FIG. 4 depicts a simplified schematic 400a of a wireless power transfer system. In simplified schematic 400a, the wireless power transmitter is represented by a voltage source Vin, a tuning capacitance C1, a wireless power transfer coil resistance R1, and a wireless power transfer coil inductance L1. Similarly, the wireless power receiver is represented by a wireless power transfer coil resistance R2, a wireless power transfer coil inductance L2, a tuning capacitance C2, and a load 441 that receives an output voltage Vo and a load current Io from the wireless power receiver. This schematic can be still further simplified to schematic 400b, which represents the load as an impedance Ro, the impedances of the wireless power transmitter and receiver as the reactance Xs and the resistance Rs, and the voltage source as a voltage source gVin.

As described above, it may be desirable to estimate the maximum power transfer capability of the system before increasing the wirelessly power transmission to a target power level. The circuit components of the simplified schematics 400a and 400b described above can be affected by the relative placement of the wireless power transmitter and the wireless power receiver with respect to each other. However, the output impedance (Ro) and voltage source gain “g” generally remain constant under different load condition, unless the system parameters change (e.g., a change in coupling coefficient caused by relative repositioning of the wireless power transmitter and receiver). Thus, the simplified equivalent circuit 400b can be characterized by three variables, g (the voltage gain), Rs (the wireless power transfer system resistance), and Xs (the wireless power transfer system reactance). These are related by the equation:

$${g}^{2} V {in}^{2} = {I}_{o}^{2} {Xs}^{2} + {{I}_{o}^{2} ( Rs + {R}_{o} )}^{2} .$$

where g is the gain described above, Vin is the input voltage, Io is the load current, Xs is the wireless power transfer system reactance, Rs is the wireless power transfer system resistance, and Ro is the load impedance.

To solve for the three unknown variables Rs, Xs, and k, the system can be operated at three different load points each having a known (or measured) input voltage Vin, output current Io, and load impedance Ro. This is depicted in plot 400c of FIG. 4. Plot 400c depicts output power Po as a function of load impedance Ro for various input voltages Vboost. The DC input voltage to the inverter of the wireless power transmitter may be, but need not necessarily be, supplied by a boost converter. As a result, it can different values depending on the operating power as, for example, it may be desirable to provide a higher input voltage at higher load conditions. In any case, plot 400c depicts three power vs. load impedance curves 441, 442, and 443 for different DC input voltage (Vboost) values. Curve 441 depicts load power as a function of load impedance for a lowest DC input voltage that can be relatively close to or equal to a minimum available DC input voltage. Curve 442 depicts load power as a function of load impedance for a relatively lower DC input voltage that can still be relatively close to a minimum available DC input voltage but can be relatively higher than that of curve 441. Finally, curve 443 depicts load power as a function of load impedance for a relatively higher DC input voltage that can be the maximum available DC input voltage.

Thus, three different operating points 441a, 441b, and 442c can be used to determine the circuit parameters g, Rs, and Xs above. More specifically, the wireless power transfer system can be operated at operating point 441a, which will include a given DC input voltage for the inverter that corresponds to the AC voltage gVin from simplified schematic 400b, a corresponding load impedance Ro, and a corresponding output current Io. Similarly, the wireless power transfer system can be operated at operating points 441b and 442c (which can have a different input voltage), resulting in additional values for gVin, Ro, and Io. These values can then be used in the following system of equations to solve for the values k, Rs, and Xs that characterize the wireless power transfer system in the given position:

$$\begin{matrix}{g}^{2} {V in}_{1}^{2} = {I}_{o 1}^{2} {Xs}^{2} + {{I}_{o 1}^{2} ( Rs + {R}_{o 1} )}^{2} \\ {g}^{2} {V in}_{2}^{2} = {I}_{o 2}^{2} {Xs}^{2} + {{I}_{o 2}^{2} ( Rs + {R}_{o 2} )}^{2} \\ {g}^{2} {V in}_{3}^{2} = {I}_{o 3}^{2} {Xs}^{2} + {{I}_{o 3}^{2} ( Rs + {R}_{o 3} )}^{2}\end{matrix}$$

where Vin₁, Vin₂, and Vin₃ are the input voltages for the three operating points; Iₒ₁, Iₒ₂, and Iₒ₃ are the output currents for the three operating points; and Rₒ₁, Rₒ₂, and Rₒ₃ are the load impedances for the three operating points.

Thus, the control and communication software of the wireless power transmitter and/or wireless power receiver can be configured to operate the wireless power transfer system at the selected operating points, perform the required measurements, and compute the values k, Rs, and Xs that characterize the wireless power transfer system. Once these values are known, the maximum power that the wireless power transfer system can support in the given position for a given load is given by:

$${P}_{max} = \frac{{g}^{2} {Vin}_{max}^{2}}{{Xs}^{2} + {( Rs + Ro )}^{2}} Ro$$

which corresponds to point operating point 443d depicted in plot 400c.

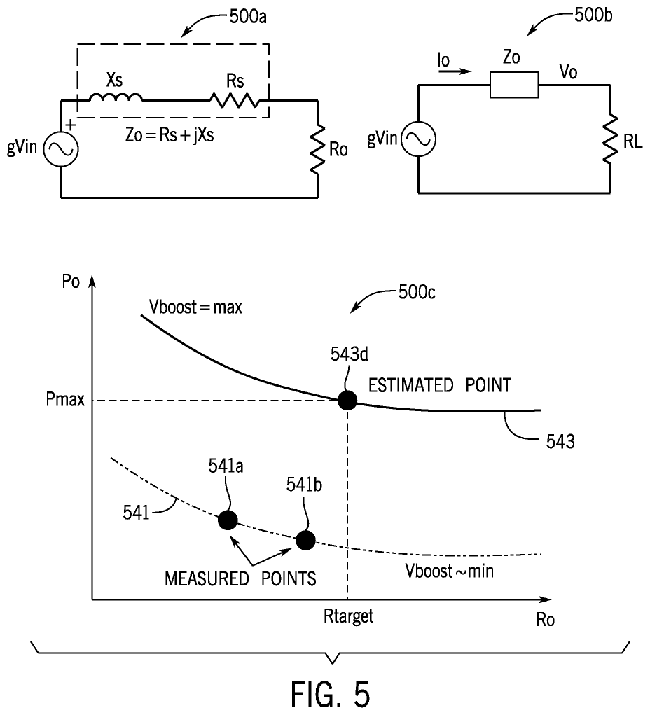

In other embodiments, the maximum power level that a wireless power transfer link can support can be determined in accordance with a two-point power estimation scheme as depicted in FIG. 5. FIG. 5 depicts a simplified schematic 500a of a wireless power transfer system, which generally corresponds to simplified schematic 400b, described above. This schematic can be still further simplified to schematic 500b, which represents the load as an impedance RL, with the impedances of the wireless power transmitter and receiver being further simplified to a single resistance Zo, and the voltage source as a voltage source gVin. This further simplification is based on the assumption that the impedances of the wireless power transfer system are predominantly resistive, which may be a more accurate assumption at relatively higher power levels, as illustrated in greater detail below.

As described above, it may be desirable to estimate the maximum power transfer capability of the system before increasing the wirelessly power transmission to a target power level. The circuit components of the simplified schematics 400a and 400b described above can be affected by the relative placement of the wireless power transmitter and the wireless power receiver with respect to each other. However, the output impedance (Ro) and voltage source gain “g” generally remain constant under different load condition, unless the system parameters change (e.g., a change in coupling coefficient caused by relative repositioning of the wireless power transmitter and receiver). Thus, the simplified equivalent circuit 500b can be characterized by only two variables, g (the voltage gain), Zo (the wireless power transfer system impedance). These are related by the equation:

gVin=IoZo+Vo

where g is the gain described above, Vin is the input voltage, Io is the load current, Zo is the wireless power transfer system resistance, and Vo is the output voltage.

To solve for the two unknown variables g and Zo, the system can be operated at two different load points each having a known (or measured) input voltage Vin, output current Io, and output voltage Vo. This is depicted in plot 500c of FIG. 5. Plot 500c depicts output power Po as a function of load impedance Ro for various input voltages Vboost. The DC input voltage to the inverter of the wireless power transmitter may be, but need not necessarily be, supplied by a boost converter. As a result, it can different values depending on the operating power as, for example, it may be desirable to provide a higher input voltage at higher load conditions. In any case, plot 400c depicts two power vs. load impedance curves 541 and 543 for different DC input voltage (Vboost) values. Curve 541 depicts load power as a function of load impedance for a lowest DC input voltage that can be relatively close to or equal to a minimum available DC input voltage. Curve 543 depicts load power as a function of load impedance for a relatively higher DC input voltage that can be the maximum available DC input voltage.

Thus, two different operating points 541a and 541b can be used to determine the circuit parameters g and Zo above. More specifically, the wireless power transfer system can be operated at operating point 541a, which will include a given DC input voltage for the inverter that corresponds to the AC voltage gVin from simplified schematic 500b, a corresponding load impedance RL, and a corresponding output current Io. Similarly, the wireless power transfer system can be operated at operating point 541b, resulting in additional values for Vo and Io. These values can then be used in the following system of equations to solve for the values g and Zo that characterize the wireless power transfer system in the given position:

gVin=Iₒ₁Zo+Vₒ₁

gVin=Iₒ₂Zo+Vₒ₂

where Vₒ₁ and Vₒ₂ are the output voltages for the two operating points; Iₒ₁ and Iₒ₂ are the output currents for the two operating points.

Thus, the control and communication software of the wireless power transmitter and/or wireless power receiver can be configured to operate the wireless power transfer system at the selected operating points, perform the required measurements, and compute the values k and Zo that characterize the wireless power transfer system. Once these values are known, the maximum power that the wireless power transfer system can support in the given position for a given load is given by different equations. For example, for fixed load impedance (RL) operation, maximum power can be given by:

$${P}_{max} = \frac{{( {gVin}_{max} )}^{2}}{{( Zo + RL )}^{2}} RL$$

Similarly, for fixed output voltage (Vo) operation at a target output voltage Vo_{target}, maximum power can be given by:

$${P}_{max} = \frac{{gVin}_{max} - {Vo}_{target}}{Zo} {Vo}_{target}$$

Likewise, for fixed output current (Io) operation at a target output current Io_{target}, maximum power can be given by:

Pₘₐₓ=(gVinₘₐₓ−Zo·Io_{target})Io_{target}

In each case, the maximum power Pₘₐₓ corresponds to operating point 543d in plot 500c of FIG. 5.

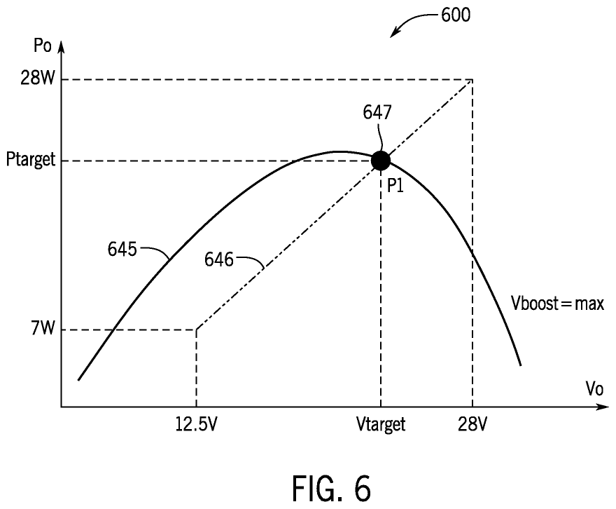

FIG. 6 illustrates a load-line power estimation technique that can be used in place of either the three-point or two-point maximum power estimation techniques described above. FIG. 6 includes a plot 600 illustrating a profile load line 646, corresponding to a wireless power transmitter. For example, some wireless power transmitters, when operating over an example range, may supply an output voltage that is a linear function of the power delivered. As but one example, over a power range from 7 W to 28 W, the voltage supplied by the wireless power transmitter may be given by:

Vo=mPo+d

where Vo is the output voltage, Po is the output power, m is the slope of the linearly increasing power as a function of voltage, and d is an offset value. As one example, at a load of 7 W, the transmitter could supply a voltage of 12.5V, while at an output power of 28 W, the transmitter could supply a voltage of 28V. Note that the example voltages and power levels given are just one example, and any other suitable values could be used in their place.

Plot 600 also depicts a system load line 645, which depicts the system power at maximum DC input voltage Vboost for a given receiver in a given position as a function:

Zo·Po=gVinₘₐₓ·Vo−Vo²

which is equivalent to:

$$Po = \frac{{gVin}_{max} - Vo}{Zo} Vo$$

with the variables as defined above. By computing the intersection of these two curves, i.e., point 647, the maximum power P1 can be determined. This can be given by:

$${Po}_{taget} = \frac{{Vo}_{target} - d}{m}$$

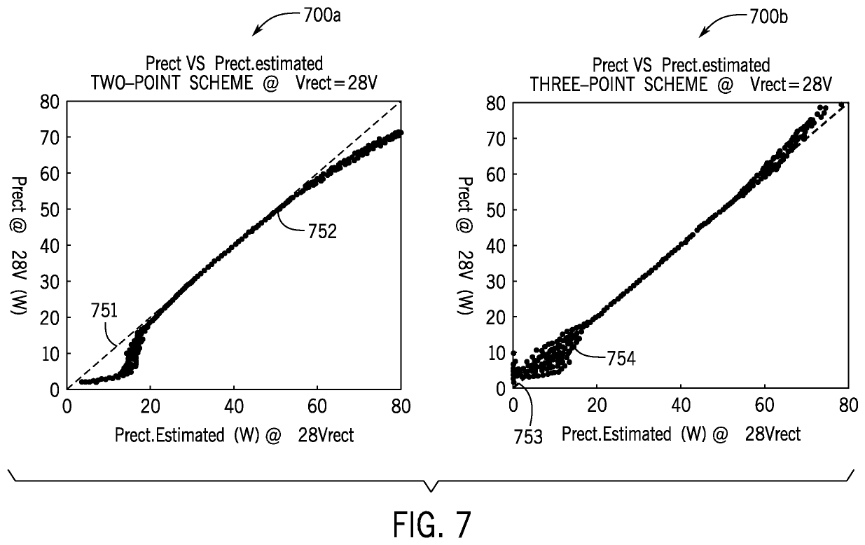

FIG. 7 illustrates exemplary accuracies of 2-point vs. 3-point power estimation techniques for an example wireless power transfer system. Plot 700a depicts a curve 751 plotting actual power (y-axis) vs. estimated power using a two-point estimation scheme as described above with reference to FIG. 5. Data point cloud 752 depicts actual output power values for the same system. These curves and data points correspond to just one example system, and thus the specific numerical values are not critical. As can be seen, above 20 W and below 60 W the two-point estimation provides good agreement with the actual power levels. Below 20 W power and above 60 W, the divergence between the predicted and actual power values can be explained at least in part by the simplifying assumption that the impedance of the wireless power transfer system is predominantly resistive, as in these other power regimes, reactive effects can have a more significant effect.

Plot 700b depicts a curve 753 plotting actual power (y-axis) vs. estimated power using a two-point estimation scheme as described above with reference to FIG. 5. Data point cloud 754 depicts actual output power values for the same system. These curves and data points correspond to just one example system, and thus the specific numerical values are not critical. As can be seen, above 20 W and below 60 W the two-point estimation provides good agreement with the actual power levels. Below 20 W power and above 60 W, the divergence between the predicted and actual power values may be smaller than in the two-point estimation because of accounting for the reactive effects, although some divergence is still seen.

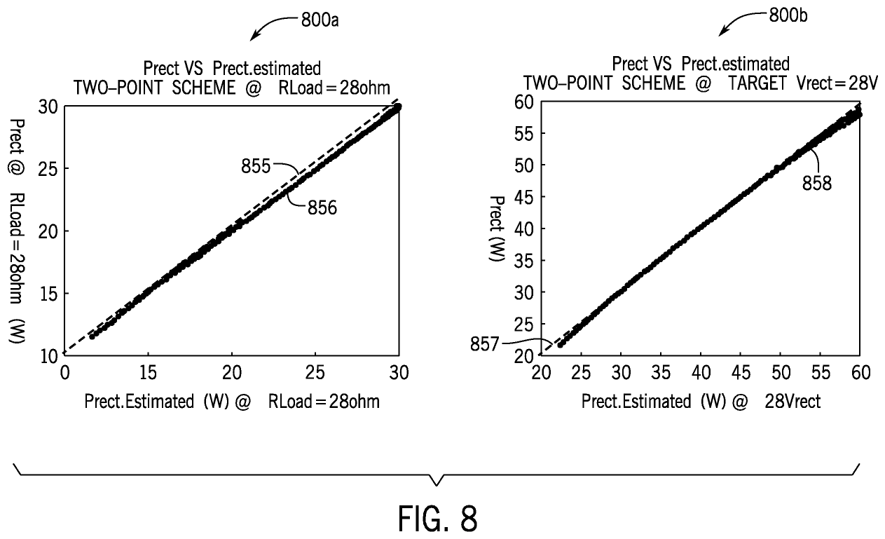

FIG. 8 illustrates exemplary accuracies of a constant load (resistance) vs. constant voltage 2-point power estimation technique. Plot 800a depicts a curve 855 plotting actual power (y-axis) vs. estimated power using a two-point estimation scheme as described above with reference to FIG. 5. Data point cloud 856 depicts actual output power values for the same system. These curves and data points correspond to just one example system, and thus the specific numerical values are not critical. As can be seen, agreement between the predicted and actual values is generally good.

Plot 800b depicts a curve 857 plotting actual power (y-axis) vs. estimated power using a two-point estimation scheme as described above with reference to FIG. 5. Data point cloud 858 depicts actual output power values for the same system. These curves and data points correspond to just one example system, and thus the specific numerical values are not critical. As with the constant load case, agreement between the predicted values and actual values is generally good over a wide operating range of interest.

Described above are various features and embodiments relating to wireless power transfer devices capable of estimating maximum power deliverable over the wireless power link. Such arrangements may be used in a variety of applications but may be particularly advantageous when used in conjunction with electronic devices such as mobile phones, tablet computers, laptop or notebook computers, and wireless power receivers including accessories, such as wireless headphones, styluses, etc. Additionally, although numerous specific features and various embodiments have been described, it is to be understood that, unless otherwise noted as being mutually exclusive, the various features and embodiments may be combined various permutations in a particular implementation. Thus, the various embodiments described above are provided by way of illustration only and should not be constructed to limit the scope of the disclosure. Various modifications and changes can be made to the principles and embodiments herein without departing from the scope of the disclosure and without departing from the scope of the claims.

The foregoing describes exemplary embodiments of wireless power transfer systems that are able to transmit certain information between the PTx and PRx in the system. The present disclosure contemplates this passage of information improves the devices' ability to provide wireless power signals to each other in an efficient manner to facilitate battery charging, such as by sharing of the devices' power handling capabilities with one another. Entities implementing the present technology should take care to ensure that, to the extent any sensitive information is used in particular implementations, that well-established privacy policies and/or privacy practices are complied with. In particular, such entities would be expected to implement and consistently apply privacy practices that are generally recognized as meeting or exceeding industry or governmental requirements for maintaining the privacy of users. Implementers should inform users where personally identifiable information is expected to be transmitted in a wireless power transfer system and allow users to “opt in” or “opt out” of participation. For instance, such information may be presented to the user when they place a device onto a power transmitter, if the power transmitter is configured to poll for sensitive information from the power receiver.

1. A wireless power transmitter including a wireless power transfer coil, an inverter that drives the wireless power transfer coil to deliver power to a wireless power receiver coupled to the wireless power transfer coil, and control circuitry coupled to the wireless power transfer coil and the inverter that:
operates the inverter to establish a first power wireless power transfer link with the wireless power receiver;
determines a maximum power level associated with the wireless power transfer link; and
transitions to a second power level wireless power transfer link, wherein the second power level is higher than the first power level and is based on the determined maximum power level associated with the wireless power transfer link;
wherein the control circuitry determines the maximum power level associated with the wireless power transfer link by:
operating the wireless power transmitter at a plurality of operating points;
measuring one or more circuit parameters associated with the plurality of operating points;
computing one or more characterizing parameters from the measured one or more circuit parameters; and
computing the maximum power level from the one or more characterizing parameters.

2. The wireless power transmitter of claim 1 wherein the plurality of operating points includes three operating points, each operating point corresponding to an input voltage Vin, and output current Io, and a load resistance Ro.

3. The wireless power transmitter of claim 2 wherein the one or more characterizing parameters include a gain g, a wireless power transfer system resistance Rs, and a wireless power transfer system reactance Xs.

4. The wireless power transmitter of claim 3 wherein the one or more characterizing parameters and the operating points are related by:
$${g}^{2} {Vin}^{2} = {I}_{o}^{2} {Xs}^{2} + {{I}_{o}^{2} ( Rs + Ro )}^{2} .$$

5. The wireless power transmitter of claim 3 wherein the maximum power level is computed by:
$${P}_{max} = \frac{{g}^{2} {Vin}_{max}^{2}}{{Xs}^{2} + {( Rs + Ro )}^{2}} Ro .$$

6. The wireless power transmitter of claim 1 wherein the plurality of operating points includes two operating points, each operating point corresponding to an output voltage Vo and an output current Io.

7. The wireless power transmitter of claim 6 wherein the one or more characterizing parameters include a gain g and a wireless power transfer system impedance Zo, wherein the wireless power transfer system Zo is a resistance.

8. The wireless power transmitter of claim 7 wherein the one or more characterizing parameters and the operating points are related by:
gVin=IoZo+Vo.

9. The wireless power transmitter of claim 8 wherein the maximum power level is computed for a fixed load resistance RL by:
$${P}_{max} = \frac{{( {gVin}_{max} )}^{2}}{{( Zo + RL )}^{2}} RL .$$

10. The wireless power transmitter of claim 8 wherein the maximum power level is computed for a fixed output voltage Vo_{target} by:
$${P}_{max} = \frac{{gVin}_{max} - {Vo}_{target}}{Zo} {Vo}_{target} .$$

11. The wireless power transmitter of claim 8 wherein the maximum power level is computed for a fixed output current Io_{target} by:
Pₘₐₓ=(gVinₘₐₓ−Zo·Io_{target})Io_{target}.

12. A method of determining a maximum power transfer level associated with a wireless power transfer link between a wireless power transmitter and a wireless power receiver, the method comprising:
operating an inverter of the wireless power transmitter to establish a lower power wireless power transfer link with the wireless power receiver;
using control circuitry of the wireless power transmitter to determine a maximum power level associated with the wireless power transfer link by:
operating the wireless power transmitter at a plurality of operating points;
measuring one or more circuit parameters associated with the plurality of operating points;
computing one or more characterizing parameters from the measured one or more circuit parameters; and
computing the maximum power level from the one or more characterizing parameters; and
operating the inverter to transition to a higher power level wireless power transfer link, wherein the higher power level is based on the determined maximum power level associated with the wireless power transfer link.

13. The method of claim 12 wherein the plurality of operating points includes three operating points, each operating point corresponding to an input voltage Vin, and output current Io, and a load resistance Ro.

14. The method of claim 13 wherein the one or more characterizing parameters include a gain g, a wireless power transfer system resistance Rs, and a wireless power transfer system reactance Xs.

15. The method of claim 14 wherein the one or more characterizing parameters and the operating points are related by:
$${g}^{2} {Vin}^{2} = {I}_{o}^{2} {Xs}^{2} + {{I}_{o}^{2} ( Rs + Ro )}^{2} .$$

16. The method of claim 14 wherein the maximum power level is computed by:
$${P}_{max} = \frac{{g}^{2} {Vin}_{max}^{2}}{{Xs}^{2} + {( Rs + Ro )}^{2}} Ro .$$

17. The method of claim 12 wherein the plurality of operating points includes two operating points, each operating point corresponding to an output voltage Vo and an output current Io.

18. The method of claim 17 wherein the one or more characterizing parameters include a gain g and a wireless power transfer system impedance Zo, wherein the wireless power transfer system Zo is a resistance.

19. The method of claim 18 wherein the one or more characterizing parameters and the operating points are related by:
gVin=IoZo+Vo.

20. The method of claim 19 wherein the maximum power level is computed for a fixed load resistance RL by:
$${P}_{max} = \frac{{( {gVin}_{max} )}^{2}}{{( Zo + RL )}^{2}} RL .$$

21. The method of claim 19 wherein the maximum power level is computed for a fixed output voltage Vo_{target} by:
$${P}_{max} = \frac{{gVin}_{max} - {Vo}_{target}}{Zo} {Vo}_{target} .$$

22. The method of claim 19 wherein the maximum power level is computed for a fixed output current Io_{target} by:
Pₘₐₓ=W(gVinₘₐₓ−Zo·Io_{target})Io_{target}.

23. A wireless power transmitter including a wireless power transfer coil, an inverter that drives the wireless power transfer coil to deliver power to a wireless power receiver coupled to the wireless power transfer coil, and control circuitry coupled to the wireless power transfer coil and the inverter that:
operates the inverter to establish a lower power wireless power transfer link with the wireless power receiver;
determines a maximum power level associated with the wireless power transfer link; and
transitions to a higher power level wireless power transfer link, wherein the higher power level is based on the determined maximum power level associated with the wireless power transfer link;
wherein the control circuitry determines the maximum power level associated with the wireless power transfer link by computing an intersection of a profile load line of a wireless power transmitter with a power load line of a wireless power transfer system including the wireless power transmitter and the wireless power receiver.

24. The wireless power transmitter of claim 23 wherein the profile load line of a wireless power transmitter is given by:
Vo=mPo+d
and the power load line is given by:
$$Po = \frac{{gVin}_{max} - Vo}{Zo} Vo$$
where Vo is an output voltage, Po is an output power, m is a slope of a linearly increasing power as a function of voltage, d is an offset value, Vinₘₐₓ is a maximum DC input voltage to the inverter, Zo is an impedance of the wireless power transfer system.

25. The wireless power transmitter of claim 24 wherein the maximum power is given by:
$${Po}_{taget} = \frac{{Vo}_{target} - d}{m} .$$
